(19) United States
(12) Patent Application Publication
(10) Pub. No.: US 2016/0172236 A1
(43) Pub. Date: Jun. 16, 2016

(54) DEVICE SUBSTRATES, INTEGRATED CIRCUITS AND METHODS FOR FABRICATING DEVICE SUBSTRATES AND INTEGRATED CIRCUITS

(71) Applicant: GLOBALFOUNDRIES Singapore Pte. Ltd., Singapore (SG)

(72) Inventors: Lian Hoon Ko, Singapore (SG); Yung Fu Chong, Singapore (SG)

(21) Appl. No.: 14/568,294

(22) Filed: Dec. 12, 2014

(51) Int. Cl. H01L 21/762; H01L 27/10; H01L 29/06

(52) U.S. Cl. CPC H01L 21/76229; H01L 29/0649; H01L 27/10

(57) ABSTRACT

Integrated circuits and methods for fabricating device substrates and integrated circuits are provided. Integrated circuits in accordance with those described herein include a semiconductor substrate with a substrate surface and having a low voltage (LV) region and a second voltage region that is either a medium voltage (MV) region or a high voltage (HV) region. The integrated circuits also have semiconductor devices thereon with isolation trenches in between them. The corners of the trenches in MV and HV regions of the integrated circuit are more rounded than the corners of the trenches in the LV region so that interference by trench corners in the MV and HV regions with the operation and performance of adjacent MV or HV device is minimized. Methods for fabricating such integrated circuits, as well as device substrates from which such integrated circuits may be fabricated, involve providing a semiconductor substrate and overlaying various oxide layers thereon, along with performing nitride pullback techniques, and forming isolation trenches by shallow trench isolation techniques to form trench corners in MV and HV regions that are more rounded than trench corners in the LV region.

### TECHNICAL FIELD

The present disclosure generally relates to integrated circuits, and methods for fabricating device substrates and integrated circuits. More particularly, the present disclosure relates to methods for fabricating device substrates having STI trenches with different trench corners in low, and medium and/or high voltage regions thereof, methods for fabricating integrated circuits having low and medium, and/or high voltage devices formed on such device substrates, and integrated circuits having low and medium and/or high voltage devices on such device substrates.

### BACKGROUND

In modern integrated circuits, a very high number of individual semiconductor devices, such as field effect transistors in the form of CMOS, NMOS, PMOS elements, resistors, capacitors and the like, are formed on a single chip area. However, such semiconductor devices should be properly isolated from one another to function properly. When semiconductor devices are not properly isolated from one another, leakage currents may occur, causing power dissipation, unwanted electric fields, noise-margin degradation, and voltage shift on dynamic nodes.

Shallow trench isolation (STI) structures improve electromagnetic isolation between semiconductor devices. To form an STI structure, typically a narrow trench is formed in a semiconductor substrate and the trench is filled with an insulating material prior to fabrication of semiconductor devices.

After filling the trench, it is sometimes found that sharp corners or divots tend to form in the isolation material during processes such as etching and deglazing, etc. To reduce the tendency of such sharp corners and divots to form, the technique of nitride pull back was developed. During the nitride pull back process, a nitride layer is formed over the substrate and the STI trench is cut or etched through the nitride layer and into the substrate. Nitride pull back involves laterally recessing the edge of the nitride layer from the corner of the STI trench at the interface between the substrate and nitride layer to form a broader corner or shoulder from the substrate. The trench and lateral recesses are then filled with isolation material. This technique allows the deposited isolation material to extend upward and outward from the isolation trench over the trench corners, thereby reducing the tendency of sharp corners or oxide divots to form in the trench isolation material during subsequent processing.

Even after implementing nitride pullback, however, the profile shape of trench corners formed by the substrate may be sufficiently sharp or angular to allow formation of strong electrical fields at these corners that interfere with the operation or performance of adjacent medium or high voltage semiconductor devices. These unintentional electric fields interfere by, for example, producing undesirable kinks in the I-V characteristics of the adjacent and/or other nearby semiconductor devices, as well as generating higher off-current and degrading any gate oxide. These issues are of less concern for low voltage devices (i.e., semiconductor devices having operating voltages of no more than about 1.4 V), but become more severe in the presence of medium and high voltage devices (i.e., semiconductor devices having operating voltages of at least about 5 volts (V). Other techniques for forming more rounded trench corners that would minimize or avoid these problems for medium and high voltage devices presently exist. However, using those same techniques for forming trench corners proximate low voltage devices on semiconductor devices and integrated circuits often causes other problems.

Accordingly, it is desirable to provide integrated circuits that have a low voltage device, as well as a medium voltage device, a high voltage device, or both, and STI trenches between the different voltage devices that have different trench corners suitable to properly isolate the different voltage devices. It is also desirable to provide methods for fabricating such integrated circuits. In addition, it is desirable to provide methods for fabricating device substrates having different voltage regions with STI trenches defining different voltage device-forming areas therein and having different trench corners suitable for different voltage devices to be formed thereon. Furthermore, other desirable features and characteristics of the methods and apparatus contemplated herein will become apparent from the subsequent detailed description of the invention and the appended claims, taken in conjunction with the accompanying drawings.

### BRIEF SUMMARY

Integrated circuits and methods for fabricating device substrates and integrated circuits are provided herein. In an exemplary embodiment, a method for fabricating a device substrate comprises the steps of: providing a semiconductor substrate with a substrate surface and having a low voltage (LV) region and a second voltage region that is either a medium voltage (MV) region or a high voltage (HV) region; forming a pad nitride layer overlying the substrate surface; forming a trench in the second voltage region such that the semiconductor substrate has a shoulder in the second voltage region; laterally recessing the pad nitride layer proximate the shoulder of the trench in the second voltage region; forming an oxide layer lining the trench and the shoulder in the second voltage region; forming an LV trench in the LV region such that the semiconductor substrate has a shoulder in the LV voltage region; laterally recessing the pad nitride layer proximate the LV shoulder in the LV region; and forming oxide layers lining each of the LV trench and LV shoulder and the trench and shoulder in the second voltage region, wherein the LV shoulder and oxide layer thereon form an LV trench corner, and wherein the shoulder in the second voltage region and the oxide layer thereon form a trench corner in the second voltage region that is more rounded than the LV corner.

In another embodiment, a method is provided for fabricating integrated circuits having different isolation trench corners between low, medium and high voltage devices thereof. More particularly, the method comprises: providing a semiconductor substrate with a substrate surface and having a low voltage (LV) region and a second voltage region that is either a medium voltage (MV) region or a high voltage (HV) region; forming a pad nitride layer overlying the substrate surface; forming a trench in the second voltage region such that the semiconductor substrate has a shoulder in the second voltage region; laterally recessing the pad nitride layer proximate the shoulder of the trench in the second voltage region; forming an oxide layer lining the trench and the shoulder in the second voltage region; forming an LV trench in the LV region such that the semiconductor substrate has an LV shoulder in the LV region; laterally recessing the pad nitride layer proximate the LV shoulder in the LV region; and forming oxide layers lining each of the LV trench and LV shoulder and the trench and shoulder in the second voltage region, wherein the LV shoulder and oxide layer thereon form an LV trench corner, and wherein the shoulder in the second voltage region and the oxide layer thereon form a trench corner in the second voltage region that is more rounded than the LV corner. The method for fabricating the integrated circuit further comprises forming an LV device having an operating voltage of no more than about 1.4 volts (V) in the LV region of the semiconductor wafer, and forming an MV device or an HV device having an operating voltage of at least about 5 V in the second voltage region of the semiconductor wafer.

In still another embodiment, an integrated circuit is provided that comprises: a substrate having a substrate surface; a low voltage (LV) region; an LV trench in the LV region, wherein the LV trench defines an LV device-forming area, and the substrate in LV region has an LV shoulder adjacent the LV trench, wherein an LV oxide layer lines the LV trench and the LV shoulder, and wherein the LV shoulder and LV oxide layer thereon form an LV trench corner; a second voltage region that is either a medium voltage (MV) region or a high voltage (HV) region; a second trench located in the second voltage region, wherein the second trench defines a second device-forming area, and the substrate in the second voltage region has a shoulder adjacent the second trench, wherein an oxide layer lines the second trench and the shoulder in the second voltage region, and wherein the shoulder in the second voltage region and oxide layer thereon form a trench corner that is more rounded than the LV trench corner; an LV device on the LV device-forming area in the LV region; and a second device on the second device-forming area in the second voltage region.

### BRIEF DESCRIPTION OF THE DRAWINGS

The present invention will hereinafter be described in conjunction with the following drawing figures, wherein like numerals denote like elements, and wherein:

FIGS. 1-9 are cross-sectional views of a semiconductor substrate in various stages of production for describing a method for fabricating a device substrate and an integrated circuit in accordance with an exemplary embodiment.

### DETAILED DESCRIPTION

The following detailed description is merely exemplary in nature and is not intended to limit the methods and apparatus disclosed herein or the application and uses of the methods and apparatus. Furthermore, there is no intention to be bound by any theory presented in the preceding background or the following detailed description.

As described above, when low voltage devices and medium or high voltage devices are both on the same device substrate and are separated by STI trenches, relatively sharp trench corners of the STI trenches allow unintended electric fields to develop. These unintended electric fields interfere with performance of the medium and high voltage devices, but not necessarily with the low voltage devices. Creating more rounded trench corners across the device substrate during its fabrication using aggressive STI liner thermal oxidation is not an acceptable solution because other problems arise proximate to the low voltage devices, including excessive silicon consumption and inability to meet strict active design requirements. Thus, the technology contemplated and described herein provides integrated circuits with device substrates upon which various voltage devices may be formed between STI trenches with differently shaped trench corners, i.e., trench corners adjacent low voltage device-forming areas on the device substrate with relatively sharp profiles and trench corners adjacent medium or high voltage device-forming areas that are rounder than the trench corners adjacent low voltage device-forming areas. Methods for making the aforesaid device substrates and integrated circuits are also provided and will be described in detail first below, whereby the structures of the device substrate and the integrated circuit will also become clearer.

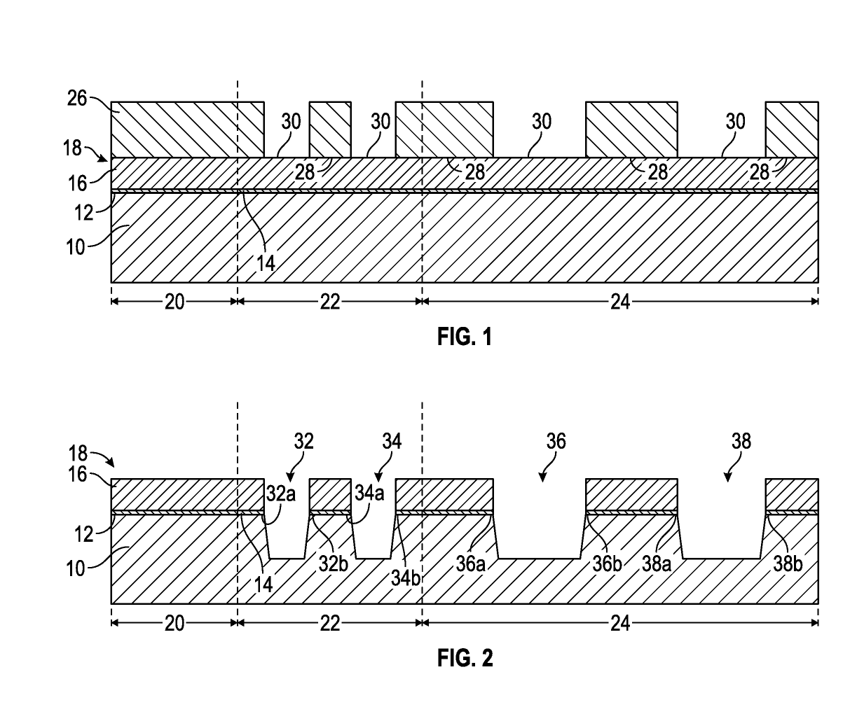

FIGS. 1-8 are cross-sectional views of a semiconductor substrate 10 in various stages of fabrication to describe a method for fabricating the above described device substrate 18 and integrated circuit 100, according to an exemplary embodiment. Initially, as shown in FIG. 1, the method includes providing a semiconductor substrate 10 having a substrate surface 12. As used herein, the term “semiconductor substrate” will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. In addition, “semiconductor material” encompasses other materials such as relatively pure and impurity-doped germanium, gallium arsenide, zinc oxide, glass, and the like. The semiconductor material is preferably a silicon substrate. The silicon substrate may be a bulk silicon wafer, as illustrated, or may be a thin layer of silicon on an insulating layer (commonly known as silicon-on-insulator or SOI) that, in turn, is supported by a carrier wafer.

As also shown in FIG. 1, the method also includes forming a pad nitride layer 16 overlaying the semiconductor substrate 10, i.e., on the substrate surface 12, to form a device substrate 18. As used herein, the terms “overlay” and “overlaying” means “on” or “over” such that the pad nitride layer 16 is either on the semiconductor substrate 10 or is over the semiconductor substrate 10, as for example, when another intervening layer, such as an oxide layer 14, is between the semiconductor substrate 10 and the pad nitride layer 16. In some embodiments, the pad nitride layer 16 is from about 1000 to about 2000 A thick. The method may also, optionally, include forming a pad oxide layer 14 directly overlaying the semiconductor substrate 10, in which case, the pad nitride layer 16 would overlay the pad oxide layer 14 to form the device substrate 18, as shown in the embodiment of FIG. 1. In some embodiments, for example, the pad oxide layer 14 is from about 50 to about 150 angstroms (A) thick.

The resulting device substrate 18 has a low voltage (LV) region 20 and a second voltage region 22, which is either a medium voltage (MV) region or a high voltage (HV) region. It is noted that in some embodiments, the device substrate 18 may further include a third voltage region 24 that may also be either an MV region or an HV region. For example, without limitation, as shown in FIGS. 1-8, in an exemplary embodiment, the device substrate 18 has an LV region 20, an MV region 22 adjacent to the LV region 20, and an HV region 24 adjacent to the MV region 22 and on the opposite side of the MV region from the LV region. This arrangement of different voltage regions 20, 22, 24 may be varied as long as the device substrate 18 includes at least one LV region 20 and at least a second voltage region 22 that may be either an MV region or an HV region. Further variations that are not specifically shown include embodiments in which the wafer includes an LV region and one HV region adjacent to the LV region, or in which the device substrate includes an LV region, an HV region adjacent thereto, and an MV region adjacent to the HV region. Other possible embodiments include device substrates having an LV region, a first HV region adjacent to the LV region, and another HV region adjacent to the first HV region, or even device substrates having two HV regions that are both adjacent to the LV region (for example, the LV region may be located in between the two HV regions). Furthermore, some embodiments may use device substrates that have an LV region, an HV region adjacent thereto, as well as an MV region adjacent to the HV region and having one corner adjacent the corner of the LV region, and a second HV region adjacent to both the MV region and the LV region, similar to the red and black squares on a checker board. The device substrates may include more than one of any of the different voltage regions, or more than one of each of LV, MV, and HV regions and, as will be recognized by persons of ordinary skill in the relevant art, a nearly limitless number of arrangements are possible and contemplated as within the scope of the method described herein.

As also depicted in FIG. 1, the method for fabricating the device substrate 18 may further include patterning the device substrate 18 by overlaying a patterned first mask layer 26 thereon that provides guidance during formation of trenches in the device substrate 18. More particularly, in the embodiment shown in FIG. 1, the first mask layer 26 has a pattern that covers the entire LV region 20 and covers a predetermined area 28 of the second voltage region 22, and leaves a target area 30 of the second voltage region 22 exposed. In an embodiment, as illustrated in FIG. 1, the patterned first mask layer 26 may also cover a predetermined area 28 of HV region 24, leaving target area 30 of HV region area 24 exposed.

With reference now to FIG. 2, after the patterning step, a trench 32 is formed having a shoulder 32a proximate the substrate surface 12 in the second voltage region 22, thereby producing a partially trenched device substrate 18. In simple terms, forming the trench 32 involves removing material from within the exposed target area 30 from the pad nitride layer 16, the pad oxide layer 14 (where present) and a portion of the semiconductor substrate 10 from the device substrate 18. More specifically, the trench 32 is typically formed by shallow trench isolation (STI) techniques which involve dry or plasma etching methods to remove the material as stated above. The dry or plasma etching methods are also typically anisotropic. In some embodiments for example, without limitation, the trench 32 may have a depth of from about 0.1 to about 0.4 microns and a width of from about 0.03 to about 2 microns.

As in the embodiment shown in FIG. 2, more than one trench 32, 34, 36, 38 may be formed in the device substrate 18, and each trench 32, 34, 36, 38 will typically have a pair of shoulders 32a, 32b, 34a, 34b, 36a, 36b, 38a, 38b, respectively. After the one or more trenches 32, 34, 36, 38 are formed, the first mask layer 26 is removed, leaving the partially trenched device substrate 18 including the pad oxide layer 14, the pad nitride layer 16 and the semiconductor substrate 10. Hereinafter, when a method step is expressed in terms of a single trench (e.g., trench 32 of FIG. 2) and the area proximate thereto, it is to be understood that one or more trenches may in fact be present and that, when more than one trench (e.g., trenches 32, 34, 36, 38 of FIG. 2) is actually present, the method step applies to each of the trenches present in a particular voltage region.

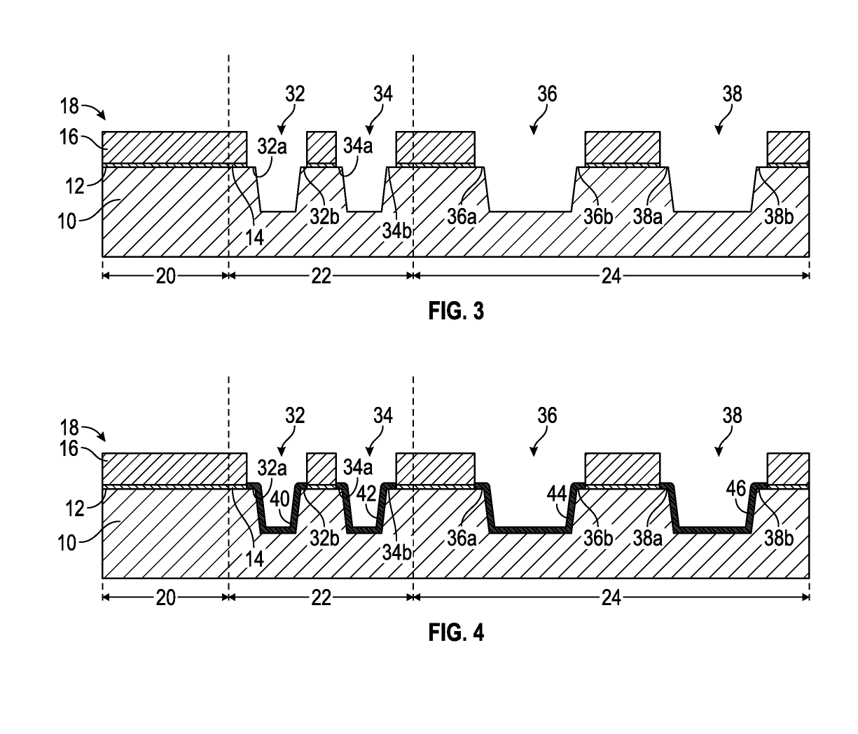

Turning now to FIG. 3, after formation of the trenches 32, 34, 36, 38 and removal of the first mask layer 26 (where used), the method involves laterally recessing the pad nitride layer 16 proximate the shoulder 32a of the trench 32 in the second voltage region 22. This lateral recessing is sometimes referred to as “nitride pullback,” and may be accomplished by any one of various nitride pullback techniques as are known now or in the future to persons of ordinary skill in the relevant art. For example, without limitation, in some embodiments, the nitride pull back may be accomplished by wet etching using an agent such as hot phosphorous. Alternatively, a plasma or other dry etch process may be used to perform the nitride pull back step. As shown in FIG. 3, the nitride pullback laterally recesses the pad nitride 16, as well as the pad oxide 14 where present, proximate each shoulder 32a, 32b, 34a, 34b of each trench 32, 34, respectively, in the second voltage (MV) region 22, as well as each shoulder 36a, 36b, 38a, 38b of each trench 36, 38, respectively, in the third voltage (HV) region 24. The pad nitride layer 16 (and the pad oxide layer 14) is recessed/pulled back from about 50 A to about 250 A from the edge of each shoulder 32a, 32b, 34a, 34b, 36a, 36b, 38a, 38b.

After nitride pullback has been performed, the method involves forming an oxide layer 40 lining the trench 32 and shoulder 32a in the second voltage region 22. The oxide layer 40 formed in the second voltage region 22 during this first oxide layer forming step has a thickness of from about 50 A to about 150 A. More particularly, as shown in FIG. 4, an oxide layer 40, 42, 44, 46 is formed lining each trench 32, 34, 36, 38 and their shoulders 32a, 32b, 34a, 34b, 36a, 36b, 38a, 38b in the second voltage (MV) and third voltage (HV) regions 22, 24, respectively. Each oxide layer 40, 42, 44, 46 has a thickness of from about 50 A to about 150 A. For example, the oxide layer 40 may be formed by thermal oxidation of the partially trenched device substrate 18. Additionally, the thermal oxidation may, for example, be performed using a furnace, under dry conditions and in the presence of an oxygen-containing gas, at a temperature of from about 800° C. to about 1150° C.

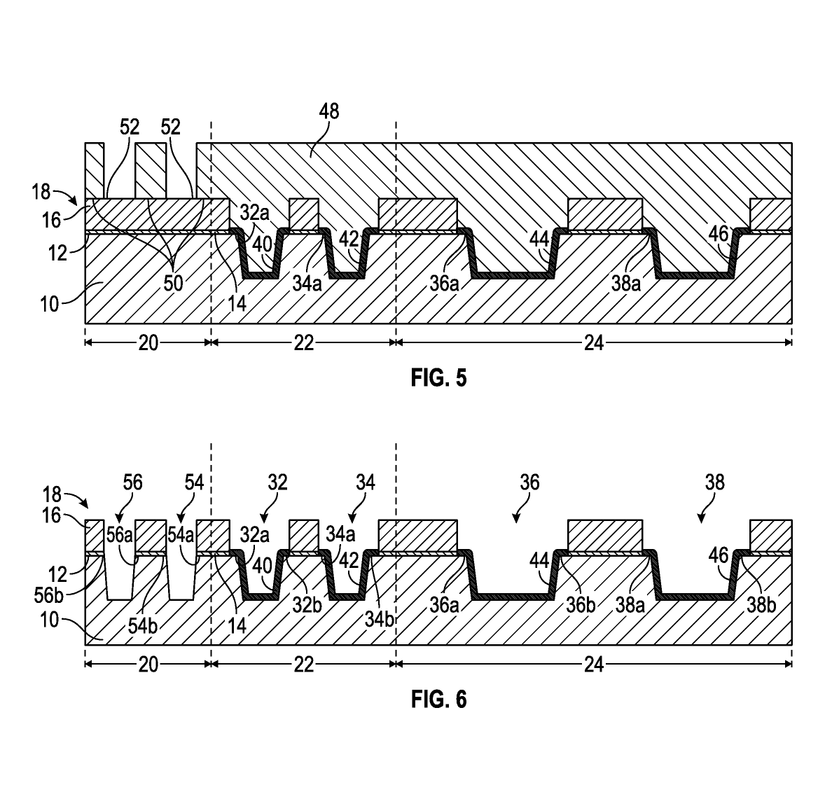

After formation of oxide layers 40, 42, 44, 46 lining each trench 32, 34, 36, 38, the partially trenched device substrate 18 may again be patterned by overlaying a second patterned mask layer 48 thereon, as illustrated in FIG. 5. The second mask layer 48 provides guidance during formation of trenches in the partially trenched device substrate 18 by covering the second voltage region 22 and lined trench 32 therein, and also covering a predetermined area 50 of the LV region 20, and leaving a target area 52 of the LV region 20 exposed. More particularly, the second mask layer 48 has a pattern that covers the second voltage (MV) region 22, including the oxide layers 40, 42 lining the trenches 32, 34 and their shoulders 32a, 32b, 34a, 34b, respectively, and the third voltage (HV) region 24, including the oxide layers 44, 46 lining the trenches 36, 38 and their shoulders 36a, 36b, 38a, 38b, respectively.

Referring to FIG. 6, with the second patterned mask layer 48 in place on the partially trenched device substrate 18, an LV trench 54 is formed in the LV region 20 having an LV shoulder 54a proximate the substrate surface 12. It is noted that in some embodiments, the step of forming an LV trench 54 in the LV region 20 may form more than one LV trench in the LV region, such as two trenches 54, 56, each having a pair of shoulders 54a, 54b, 56a, 56b, respectively, proximate the substrate surface 12. This step of forming the LV trench 54 involves removing material from within the exposed target area 52 from the pad nitride layer 16, the pad oxide layer 14 and a portion of the semiconductor substrate 10 of the partially trenched device substrate 18, such as by shallow trench isolation (STI) techniques described above. Thereafter, when a second patterned mask layer 48 has been used, it is removed to leave a trenched device substrate 18 (see FIG. 6).

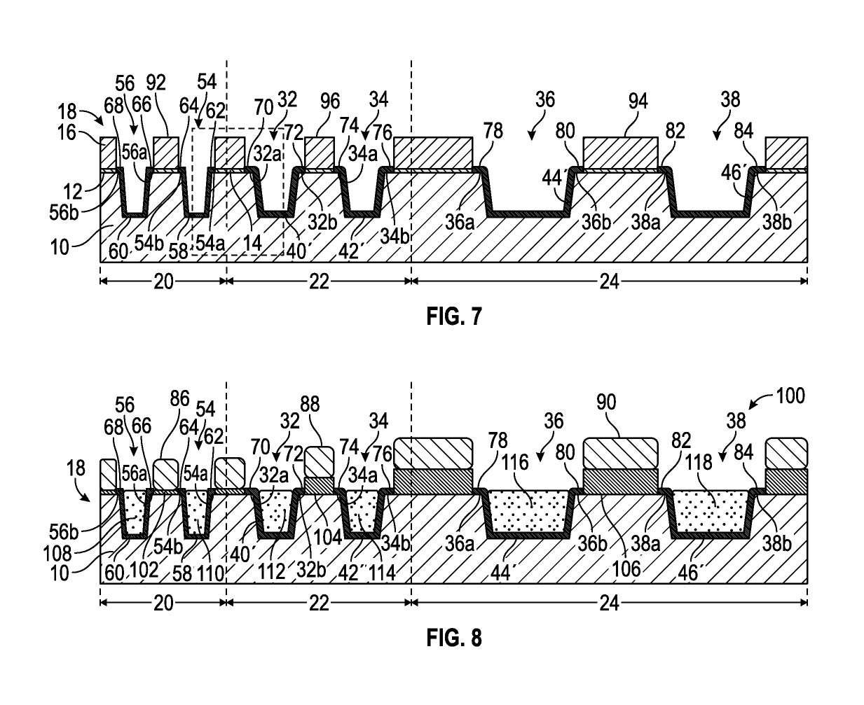

Although not shown separately, it can be seen in FIG. 7 that a second nitride pullback is performed to laterally recess the pad nitride layer 16 proximate the LV shoulder 54a of the LV trench 54 in the LV region 20. This second nitride pullback is also accomplished by any one of various nitride pullback techniques as are known now or in the future to persons of ordinary skill in the relevant art. As shown in FIG. 7, the nitride pullback laterally recesses the pad nitride 16, as well as the pad oxide 14 where present, proximate each LV shoulder 54a, 54b, 56a, 56b of each of the two LV trenches 54, 56, respectively. The pad nitride layer 16 (and the pad oxide layer 14) is recessed/pulled back from about 50 A to about 250 A from the edge of each shoulder 32a, 32b, 34a, 34b, 36a, 36b, 38a, 38b.

After the second nitride pullback, the method further involves forming oxide layers 58, 40′ lining each of the LV trench 54 and LV shoulder 54a and the trench 32 and shoulder 32a in the second voltage region 22. With reference to FIG. 7, an oxide layer 58 is formed lining the LV trench 54 and LV shoulder 54a, wherein the LV shoulder 54a and oxide layer 58 thereon form an LV trench corner 62. The oxide layer 58 lining the LV trench 54 and LV shoulder 54a has a thickness of from about 20 A to about 150 A.

This oxide layer-forming step adds oxide to the existing oxide layer 40 of the trench 32 and shoulder 32a of the trench 32 in the second voltage region 22 which forms a thickened oxide layer 40′ lining the trench 32 and shoulder 32a. The thickened oxide layer 40′ in the second voltage region 22 has a final thickness of from about 50 A to about 280 A. Additionally, the shoulder 32a of the trench 32 and oxide layer 40′ thereon form a trench corner 70 in the second voltage region 22 that is more rounded than the LV trench corner 62. The trench corner 70 of the trench 32 in the second voltage region 22 is sufficiently rounded to minimize interference with or alteration of electromagnetic fields created by devices to be formed in the second voltage region 22.

More particularly, in the embodiment shown in FIG. 7, oxide layers 58, 60 are formed lining each LV trench 54, 56 and their shoulders 54a, 54b, 56a, 56b, respectively, in the LV region 20. Each shoulder 54a, 54b, 56a, 56b and oxide layer 58, 60 thereon, respectively, forms a trench corner 62, 64, 66, 68, respectively, in the LV region. The oxide layer 58, 60 lining each LV trench 54, 56 and its LV shoulders 54a, 54b, 56a, 56b, respectively, has a thickness of from about 20 A to about 150 A.

Thickened oxide layers 40′, 42′, 44′, 46′ are also formed lining the trenches 32, 34, 36, 38 and their shoulders 32a, 32b, 34a, 34b, 36a, 36b, 38a, 38b in the second voltage (MV) region 22 and third voltage (HV) region 24, respectively. Consequently, each of the thickened oxide layers 40′, 42′, 44′, 46′ in the second voltage region 22 has a final thickness of from about 50 A to about 280 A. Furthermore, each shoulder 32a, 32b, 34a, 34b, 36a, 36b, 38a, 38b and thickened oxide layer 40′, 42′, 44′, 46′ thereon, respectively, forms a trench corner 70, 72, 74, 76, 78, 80, 82, 84 in the second (MV) and third (HV) voltage regions 22, 24, and each trench corner 70, 72, 74, 76, 78, 80, 82, 84 is more rounded than the LV corners 62, 64, 66, 68. Each trench corner 70, 72, 74, 76, 78, 80, 82, 84 in the second and third voltage regions 22, 24, respectively, is sufficiently rounded to minimize interference with or alteration of electromagnetic fields created by devices to be formed in the second (MV) and third (HV) voltage regions. In other words, “sufficiently rounded” trench corners minimize interference with the operation or performance of MV or HV devices adjacent thereto.

The difference in roundness between the LV trench corner 62 and the trench corner 70 in the second voltage region 22 is shown more clearly in FIG. 9. The dotted portion of the device substrate 18 shown in FIG. 7 is shown enlarged in FIG. 9. More particularly, the enlarged section shown in FIG. 9 includes an LV trench corner 62 in the LV region 20 and a trench corner 70 in the second voltage region 22, which may be either an MV or and HV region. The “roundness” of the trench corners 54, 32 may be measured and compared using the “radius of curvature” R1, R2 for each respectively. As shown in FIG. 9, the “radius of curvature” is the radius of a circle whose circumference aligns with the curved surface of the trench corner. In some exemplary embodiments, the radius of curvature R1 for each LV trench corner is in a range of from about 1 nanometer (nm) to about 25 nm and the radius of curvature R2 for each trench corner in MV and HV regions is from about 5 nm to about 30 nm.

Generally, the greater the radius of curvature of a trench corner, the more rounded the trench corner is and the less likely the trench corner is to interfere with or alter the electromagnetic fields created by devices formed adjacent thereto. In other words, the greater the radius of curvature, the more rounded the trench corner, and the more likely the trench corner is to minimize interfering with the operation or performance of MV or HV devices adjacent thereto. Thus, according to the method contemplated and described herein, the radius of curvature R2 for the trench corner 70 of the second voltage region 22 (which is either an MV or an HV region) is greater than the radius of curvature R1 for the LV trench corner 62 of the LV region 20 (i.e., R2>R1). More particularly, a “sufficiently rounded” trench corner for the trench corner 70 of the second voltage region 22 will have a radius of curvature R2 that is at least 8% greater than the radius of curvature R1 for the LV trench corner 62 of the LV region 20. As will be recognized by persons of ordinary skill, there are other advantages of having the thickened oxide layers 40′, 42′, 44′, 46′ lining the trenches 32, 34, 36, 38 and their shoulders 32a, 32b, 34a, 34b, 36a, 36b, 38a, 38b, in addition to those described above. For example, the bottom of the trenches 32, 34, 36, 38 in the second voltage (MV) region 22 and third voltage (HV) region 24, respectively are also “sufficiently rounded” by the additional oxide liner thickening process.

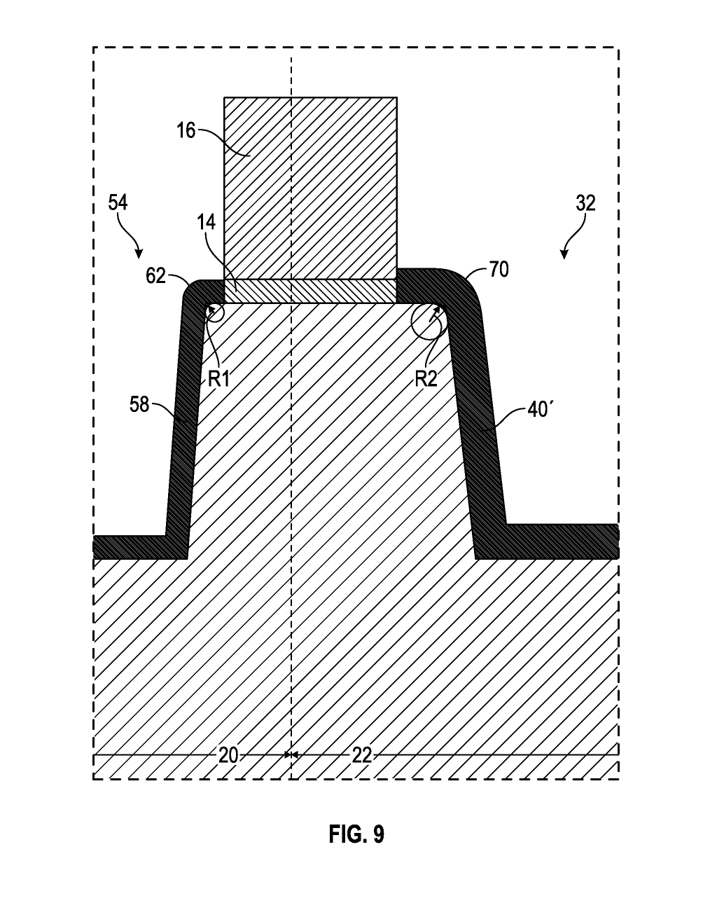

Generally, before devices such as transistors are formed on the trenched device substrate 18 fabricated according to the method described above, the LV trench 54 in the LV region 20 and the trench 32 in the second voltage region 22 are typically filled with an isolation material (see, e.g., 110, 112 in FIG. 8), such as, without limitation, silicon dioxide or another suitable dielectric material. Where the trenched device substrate 18 also includes a third voltage region 24 with a trench 36 therein, that trench 36 is also, of course filled with an isolation material (see, e.g., 116 in FIG. 8). Further processing of the device substrate 18 may then proceed. Such additional fabrication and processing techniques include, for example without limitation, chemical mechanical polishing (CMP), pad nitride strip removal, device well implantation, gate oxide formation, and poly-Si gate electrode deposition, among others.

In another exemplary embodiment, a method for fabricating an integrated circuit 100 is provided. An integrated circuit 100 fabricated in accordance with the presently described method is shown schematically in FIG. 8. In general, the method comprises fabricating a device substrate 18 as described hereinabove, followed by forming different voltage devices in the different voltage regions 20, 22, 24 of the trenched device substrate 18. Generally, each of the trenches 56, 54, 32, 34, 36, 38 is filled with isolation material 108, 110, 112, 114, 116, 118, respectively, as mentioned above and shown in FIG. 8. Optionally, various intermediate processing steps may also be applied to the device substrate 18 prior to formation of the devices, such as removal of the pad oxide (14) and pad nitride (16) layers from the device substrate 18, followed by overlaying the gate oxide layers 102, 104 and 106 on the semiconductor substrate 10 in each of the LV region 20, MV region 22 and HV region 24, respectively. Generally, the thicknesses of the gate oxide layers increase form the LV region 20, to the MV region 22 and to the HV region 24. More particularly the thickness of the gate oxide layer 102 in the LV region 20 is typically from about 16 A to about 30 A, while the thickness of the gate oxide layer 104 in the MV region 22 is typically from about 100 A to about 250 A. The thickness of the gate oxide layer 106 in the HV region 24 is typically from about 400 A to about 1000 A.

Once the device substrate 18 has been fabricated and prepared according to desired specifications, a device, such as the low voltage (LV) device 86 shown in FIG. 8, is formed in the LV region 20 of the trenched device substrate 18. More particularly, for example, the LV device 86 has an operating voltage of no more than about 1.4 volts (V) and is formed on the gate oxide layer 102 in the LV region 20. It is noted that in some embodiments, more than one LV device 86 may be formed in the LV region 20 on the device substrate 18. In other embodiments, the device substrate 18 may have more than one LV region, each of which may have one more additional LV devices formed thereon.

Additionally, the method for fabricating the integrated circuit 100 further comprises the step of forming a second voltage device 88, which may be either an MV device or an HV device, having an operating voltage of at least about 5 V, in the second voltage region 22 of the device substrate 18. In the embodiment shown in FIG. 8, the second voltage device is an MV device 88 formed overlaying the oxide layer 104 in the MV region 22. While not shown per se, it is noted that in some embodiments, more than one voltage device, which are either MV devices or HV devices, may be formed in the second voltage region 22 of the device substrate 18. Also, in some embodiments, the second voltage region may be an MV region 22 with two MV devices formed therein, and the device substrate 18 may further comprise a third voltage region which may be an HV region 24 having one or more HV devices 90 formed therein. For example, the embodiment shown in FIG. 8 includes a third voltage region which is an HV region 24, and an HV device 90 formed overlaying the gate oxide layer 106 in the HV region 24.

As will be recognized by persons of ordinary skill, there are many variations on the number and arrangement of different voltage regions that may be present on the integrated circuit 100 and the corresponding voltage devices formed thereon, in addition to those described above. For example, some embodiments of the integrated circuit 100, such as those where the second voltage region 22 is an MV region, may have multiple MV devices formed thereon, and where the second voltage region 22 is an HV region, there may be multiple HV devices formed thereon. In other embodiments, the integrated circuit 100 may have additional voltage regions beyond the second voltage region, such as a third or fourth voltage regions, each of which may have a separate corresponding voltage device formed thereon. For example, without limitation, where the integrated circuit has second and third voltage regions, and the second voltage region is an HV region, an HV device would be formed thereon, and the third voltage region is an MV region, an MV device would be formed thereon.

In another exemplary embodiment (best viewed in FIG. 7), a device substrate 18 produced by the above-described fabrication method is provided having a semiconductor substrate 10 having a substrate surface 12, an LV region 20, and a second voltage region 22 which is either a MV region or a HV region. The device substrate 18 also has an LV trench 54 in the LV region 20. The LV trench 54 has an LV shoulder 54a and an LV oxide layer 58 lining the LV trench 54 and the LV shoulder 54a. Together, the LV shoulder 54a and the oxide layer 58 thereon form an LV trench corner 62 having a radius of curvature R1 (see, e.g., FIG. 9) in a range of from about 1 nm to about 25 nm. The LV oxide layer 58 has a thickness of from about 20 A to about 150 A.

Additionally, the device substrate 18 has a second trench 32 in the second voltage region 22, and the second trench 32 has a shoulder 32a and an oxide layer 40′ lining the second trench 32 and its shoulder 32a. The shoulder 32a of the second trench 32 and oxide layer 40′ thereon form a trench corner 70 that is more rounded than the LV trench corner 62. Generally, the trench corner 70 in the second voltage region 22 is, as described above, sufficiently rounded to minimize interference with or alteration of electromagnetic fields created by devices to be formed adjacent thereto. In other words, the rounded profile of the trench corner 70 of the trench 32 in the second voltage region 22 of the semiconductor device 100 is sufficiently rounded to minimize interfering with the operation or performance of a medium voltage device (MV) 88 or a high voltage (HV) 90 device to be formed adjacent thereto (see, e.g., FIG. 8). The trench corner 70 in the second voltage region 22 has a radius of curvature R2 that is at least 8% greater than the radius of curvature R1 of the LV corner in the LV region 20. Additional details and possible alternatives for the device substrates contemplated herein have been described and proposed hereinabove in connection with the description of the methods for fabricating them.

In still another exemplary embodiment, an integrated circuit 100 is provided (see FIG. 8) that comprises the device substrate 18 described above (and shown in FIG. 7), where the LV trench 54 defines an LV device-forming area 92 and the second trench 32 defines a second device-forming area 96. Additionally, where the device substrate 18 has a third voltage region 24 with a third trench 36, as in FIG. 8, the third trench 36 defines a third device-forming area 94. As shown in FIG. 8, the semiconductor device 100 also has an LV device 86 on the LV device-forming area 92 in the LV region 20, as well as a second device 88 on the second device-forming area 94 in the second voltage region 22. Where the second voltage region 22 is an MV region, as shown in FIG. 8, the second device 88 will be an MV device, but where the second voltage region 22 is an HV region, the second device 88 will be an HV device. In embodiments, such as shown in FIG. 8, where the semiconductor device 100 has a third voltage region 24, with a third trench 36 and a third device-forming area 96 formed thereby, the semiconductor device 100 further includes a third device 90 on the third device-forming area 96. Again, it is noted that where the third voltage region 24 is an HV region, as shown in FIG. 8, the third device 90 will be an HV device, but where the third voltage region 24 is an MV region, the third device 90 will be an MV device.

One or more of the LV, second and third devices may be, for example, without limitation, a transistor, a resistor, or a memory cell. Furthermore, LV devices have an operating voltage of no more than about 1.4 V, while MV and HV devices each, independently, have an operating voltage of at least about 5 V.

While at least one exemplary embodiment has been presented in the foregoing detailed description of the semiconductor devices and methods for making same, it should be appreciated that a vast number of variations exist. It should also be appreciated that the exemplary embodiment or exemplary embodiments are only examples, and are not intended to limit the scope, applicability, or configuration of the semiconductor devices or methods described herein in any way. Rather, the foregoing detailed description will provide those skilled in the art with a convenient road map for implementing an exemplary embodiment of the semiconductor device and methods for making same. It being understood that various changes may be made in the function and arrangement of elements described in an exemplary embodiment without departing from the scope of the semiconductor devices and methods for making same, as set forth in the appended claims.

1. A method for fabricating a device substrate, the method comprising the steps of:
providing a semiconductor substrate with a substrate surface and having a low voltage (LV) region and a second voltage region that is either a medium voltage (MV) region or a high voltage (HV) region;
forming a pad nitride layer overlying the substrate surface;
forming a trench in the second voltage region such that the semiconductor substrate has a shoulder in the second voltage region;
laterally recessing the pad nitride layer proximate the shoulder of the trench in the second voltage region;
forming an oxide layer lining the trench and the shoulder in the second voltage region;
forming an LV trench in the LV region such that the semiconductor substrate has an LV shoulder in the LV region;
laterally recessing the pad nitride layer proximate the LV shoulder in the LV region; and
forming oxide layers lining each of the LV trench and LV shoulder and the trench and shoulder in the second voltage region, wherein the LV shoulder and oxide layer thereon form an LV trench corner, and wherein the shoulder in the second voltage region and the oxide layer thereon form a trench corner in the second voltage region that is more rounded than the LV corner.

2. The method of claim 1, wherein the trench corner in the second voltage region is sufficiently rounded to minimize interference with or alteration of electromagnetic fields created by devices to be formed adjacent thereto.

3. The method of claim 1, wherein the step of forming an oxide layer lining the trench and the shoulder in the second voltage region forms a oxide layer having a thickness of from about 50 Angstroms (A) to about 150 A; and
wherein the step of forming an oxide layer lining each of the LV trench and LV shoulder in the LV region and the trench and shoulder in the second voltage region forms an oxide layer lining the LV trench and LV shoulder having a thickness of from about 20 A to about 150 A, and an oxide layer lining the trench and corner in the second voltage region having a thickness of from about 50 A to about 280 A.

4. The method of claim 1, wherein the steps of forming a trench in the second voltage region and forming an LV trench in the LV voltage region are each performed, independently, by removing material from within the exposed target area from the pad nitride layer and a portion of the semiconductor substrate in each of the second voltage region and the LV voltage region, respectively.

5. The method of claim 1, wherein:
the step of providing a semiconductor substrate provides a semiconductor substrate further having a third voltage region which is either an MV region when the second voltage region is an HV region, or an HV region when the second voltage region is an MV region, and wherein
the step of forming a trench in the second voltage region further comprises forming a trench in the third voltage region;
the step of laterally recessing the pad nitride layer further comprises laterally recessing the pad nitride layer proximate the shoulder of the trench in the third voltage region;
the step of forming an oxide layer lining the trench and shoulder in the second voltage region further comprises forming an oxide layer lining the trench and shoulder in the third voltage region; and
the step of forming oxide layers lining each of the LV trench and LV shoulder in the LV region and the trench and shoulder in the second voltage region, further comprises forming an oxide layer lining the trench and shoulder in the third voltage region wherein the shoulder of the trench in the third voltage region and the oxide layer thereon form a trench corner in the third voltage region that is more rounded than the LV corner.

6. The method of claim 1, wherein forming the LV trench and the trench on the second voltage region is accomplished using a dry or plasma etching technique.

7. A method for fabricating an integrated circuit, the method comprising the steps of:
providing a semiconductor substrate with a substrate surface and having a low voltage (LV) region and a second voltage region that is either a medium voltage (MV) region or a high voltage (HV) region;
forming a pad nitride layer overlying the substrate surface;
forming a trench in the second voltage region such that the semiconductor substrate has a shoulder in the second voltage region;
laterally recessing the pad nitride layer proximate the shoulder of the trench in the second voltage region;
forming an oxide layer lining the trench and the shoulder in the second voltage region;
forming an LV trench in the LV region such that the semiconductor substrate has an LV shoulder in the LV region;
laterally recessing the pad nitride layer proximate the LV shoulder in the LV region;
forming oxide layers lining each of the LV trench and LV shoulder and the trench and shoulder in the second voltage region, wherein the LV shoulder and oxide layer thereon form an LV trench corner, and wherein the shoulder of the trench in the second voltage region and the oxide layer thereon form a trench corner in the second voltage region that is more rounded than the LV corner;
forming an LV device having an operating voltage of no more than about 1.4 volts (V) in the LV region; and
forming an MV device or an HV device having an operating voltage of at least about 5 V in the second voltage region.

8. The method of claim 7, wherein the trench corner in the second voltage region is sufficiently rounded to minimize interference with or alteration of electromagnetic fields created by devices to be formed adjacent thereto.

9. The method of claim 7, wherein the step of forming an oxide layer lining the trench and the shoulder in the second voltage region forms a oxide layer having a thickness of from about 50 Angstroms (A) to about 150 A; and
wherein the step of forming an oxide layer lining each of the LV trench and LV shoulder in the LV region and the trench and shoulder in the second voltage region forms an oxide layer lining the LV trench and LV shoulder having a thickness of from about 20 A to about 150 A, and forms an oxide layer lining the trench and corner in the second voltage region to a thickness of from about 50 A to about 280 A.

10. The method of claim 7, wherein:
the step of providing a semiconductor substrate provides a semiconductor substrate further having a third voltage region which is either an MV region when the second voltage region is an HV region, or an HV region when the second voltage region is an MV region, and wherein
the step of forming a trench having a shoulder in the second voltage region further comprises forming a trench having a shoulder in the third voltage region;
the step of laterally recessing the pad nitride layer further comprises laterally recessing the pad nitride layer proximate the shoulder of the trench in the third voltage region;
the step of forming an oxide layer lining the trench and shoulder in the second voltage region further comprises forming an oxide layer lining the trench and shoulder in the third voltage region; and
the step of forming oxide layers lining each of the LV trench and LV shoulder in the LV region and the trench and shoulder in the second voltage region, further comprises forming an oxide layer lining the trench and shoulder in the third voltage region wherein the shoulder of the trench in the third voltage region and the oxide layer thereon form a trench corner in the third voltage region that is more rounded than the LV corner.

11. An integrated circuit comprising:
a substrate having a substrate surface;
a low voltage (LV) region;
an LV trench in the LV region, wherein the LV trench defines an LV device-forming area, and the substrate in LV region has an LV shoulder adjacent the LV trench, wherein an LV oxide layer lines the LV trench and the LV shoulder, and wherein the LV shoulder and LV oxide layer thereon form an LV trench corner;
a second voltage region that is either a medium voltage (MV) region or a high voltage (HV) region;
a second trench located in the second voltage region, wherein the second trench defines a second device-forming area, and the substrate in the second voltage region has a shoulder adjacent the second trench, wherein an oxide layer lines the second trench and the shoulder in the second voltage region, and wherein the shoulder in the second voltage region and oxide layer thereon form a trench corner that is more rounded than the LV trench corner;
an LV device on the LV device-forming area in the LV region; and
a second device on the second device-forming area in the second voltage region.

12. The integrated circuit of claim 11, wherein the trench corner is sufficiently rounded to minimize interference with or alteration of electromagnetic fields created by devices adjacent thereto.

13. The integrated circuit of claim 11, wherein the LV trench corner has a radius of curvature, R₁, and the trench corner in the second voltage region has a radius of curvature, R₂, and wherein R₂ is at least 8% greater than R₁.

14. The integrated circuit of claim 11, wherein the LV oxide layer has a thickness of from about 20 Angstroms (A) to about 150 A, and the oxide layer lining the second trench and the shoulder of the second trench has a thickness of from about 50 A to about 280 A.

15. The integrated circuit of claim 11, further comprising:
a third voltage region that is either a medium voltage (MV) region or a high voltage (HV) region;
a third trench located in the third voltage region, wherein the third trench defines a third device-forming area and the substrate in the third voltage region has a shoulder adjacent the third trench, wherein an oxide layer lines the third trench and the shoulder in the third voltage region, and wherein the shoulder in the third voltage region and oxide layer thereon form a trench corner that is more rounded than the LV trench corner; and
a third device on the third device-forming area in the third voltage region.

16. The integrated circuit of claim 15, wherein each of the trenches is formed by a shallow trench isolation (STI) technique.

17. The integrated circuit of claim 15, wherein when the second voltage region is a MV region, the third voltage region is a HV region, and when the second voltage region is a HV region, the third voltage region is a MV region.

18. The integrated circuit of claim 15, wherein
the second voltage region is an MV region adjacent to the LV region; the second trench is an MV trench forming an MV device-forming area and having an MV shoulder and an MV oxide layer lining the MV trench and MV shoulder; and the second device is an MV device on the MV device-forming area; and
the third voltage region is an HV region adjacent to the MV region; the third trench is an HV trench forming an HV device-forming area and having an HV shoulder and an HV oxide layer lining the HV trench and HV shoulder; and the third device is an HV device on the HV device-forming area.

19. The integrated circuit of claim 15, wherein the LV device is a transistor having an operating voltage of no more than about 1.4 volts (V), and the MV device and HV device are both transistors, each of which, independently, has an operating voltage of at least about 5 V.

20. The integrated circuit of claim 15, further comprising a pad nitride layer overlaying the pad oxide layer; wherein each of the trenches extends through the pad nitride layer and partially into the substrate.
